(19) United States
(12) Patent Application Publication
(10) Pub. No.: US 2024/0377272 A1
(43) Pub. Date: Nov. 14, 2024

(54) MEASURING DEVICE FOR DETERMINING AND/OR MONITORING AT LEAST ONE PHYSICAL AND/OR CHEMICAL MEASUREMENT VARIABLE

(71) Applicant: Endress+Hauser SE+Co. KG, Maulburg (DE)

(72) Inventors: Romuald Girardey, Blotzheim (FR); Andreas Spitz, Schopfheim (DE); Elke Schmidt, Bad Säckingen (DE); Nils Ponath, Lörrach (DE); Marcel Gfrörer, Marc (DE); Dirk Wiedmann, Lörrach (DE)

(21) Appl. No.: 18/564,644

(22) PCT Filed: May 18, 2022
(86) PCT No.: PCT/EP2022/063466

§ 371 Date: Nov. 28, 2023

(30) Foreign Application Priority Data
May 28, 2021 (DE) 10 2021 113 914.7

(51) Int. Cl. G01L 9/00

(52) U.S. Cl. CPC G01L 9/0042

(57) ABSTRACT

A measuring device for determining a physical and/or chemical measured variable comprises a sensor element having an electrical transducer for providing measured variable dependent electrical, primary signals and a sensor body having at least one metallized surface section; an on- site electronics, wherein a first area of the on-site electronics includes a plurality of first contact areas that are mechanically and electrically connected with the at least one metallized surface section of the sensor element, wherein a second area of the on-site electronics includes a plurality of second contact areas; and a circuit board that includes a plurality of third contact areas in a first region, wherein the circuit board is mechanically and electrically connected with the on-site electronics by means of the second contact areas and the third contact areas.

The invention relates to a measuring device for determining and/or monitoring at least one physical and/or chemical, measured variable.

Measuring devices determine and/or monitor a measured variable, from which a process variable is ascertained. Measuring devices of the invention are components of field devices of process and automation technology, which serve for monitoring and/or determining at least one, for example, chemical and/or physical, process variable of a medium. A large number of such field devices are manufactured and sold by the companies of the Endress+Hauser group.

The process variable to be determined by the field device can be the fill level, flow, pressure, temperature, pH value, redox potential or conductivity of the medium. The different possible measuring principles underpinning determining process variables are known in the state of the art and are thus not explained here in further detail. Field devices for measuring fill level are, especially, embodied as microwave, fill level measuring devices, ultrasonic, fill level measuring devices, time domain reflectometric, fill level measuring devices (TDR), radiometric, fill level measuring devices, capacitive, fill level measuring devices, conductive, fill level measuring devices and vibronic fill level measuring devices. Field devices for measuring flow, for instance, flow rate or flow velocity, work, in contrast, for example, according to the Coriolis-, ultrasonic-, vortex-, thermal and/or magnetically inductive measuring principles. In the case of pressure measuring devices, there are absolute-, relative-and pressure difference measuring devices. Pressure measuring devices have, for example, a measuring device for determining a pressure dependent capacitance, based on which, then, the pressure of the medium is determined.

Generally, measuring devices comprise a sensor element, which by means of an electrical transducer provides a measured variable dependent, electrical, primary signal, and an on-site electronics, which is provided for processing the electrical primary signals and operating the electrical transducer. Connected to the on-site electronics is typically an electronics unit, which is responsible, among others, for the electrical current supply, the further processing of the electrical secondary signal obtained by the on-site electronics and/or the operating of interfaces. The connection of the on-site electronics with the electronics unit occurs, as a rule, by means of a plug.

In patent application DE 10 2019 104 841 A1, a pressure sensor element with an on- site electronics embodied as a System-in-Package is described. System-in-Package methods are demanding methods of production, which occur in a clean room, and compared with conventional circuit boards work with thinner substrates as support material for the components to be arranged thereon. The housing is applied by means of an injection molding method on the measuring-and operating circuit and is composed of plastic. In such case, especially the coefficients of thermal expansion of the pressure sensor element and the on-site electronics are to be matched to one another, since otherwise thermomechanical stress and hysteresis in the pressure sensor element can easily occur.

The on-site electronics is, however, a relatively small component, such that not much space is available for provision of a plug. The accordingly small plug is, thus, difficult to interact with. Moreover, conventional plugs, which provide a connection to, for example, a circuit board, are designed only for temperatures up to about 100° C., while, in contrast, measuring devices are frequently exposed to significantly greater temperatures, e.g. of to 200° C. Also, in the region of the electronics of the measuring device, temperatures up to 150°° C. can occur.

It is, consequently, an object of the invention to provide a measuring device, which is designed for higher temperatures. Higher temperatures are, especially, temperatures up to about 150° C.

The object of the invention is achieved by a measuring device for determining and/or monitoring at least one physical and/or chemical, measured variable, comprising
a sensor element, wherein the sensor element has an electrical transducer for providing measured variable dependent, electrical, primary signals and a sensor body having at least one metallized surface section,
an on-site electronics having a housing and a measuring-and operating circuit arranged in an interior of the housing for operating the electrical transducer and for processing the primary signals, wherein a first area of the on-site electronics includes a plurality of first contact areas, which are mechanically and electrically connected with the at least one metallized surface section of the sensor element, wherein a second area of the on-site electronics includes a plurality of second contact areas, and
a circuit board, which includes a plurality of third contact areas in a first region, wherein the circuit board is mechanically and electrically connected with the on-site electronics by means of the second contact areas and the third contact areas.

The measuring device of the invention avoids the plug and the problems connected therewith, in that the circuit board is connected with the on-site electronics without an intermediate element. For this, the on-site electronics is equipped on the, especially oppositely lying, first and second areas with the first and second contact areas. In the manufacture, as a rule, firstly, the on-site electronics is connected, for example, soldered, with the sensor element before, in a later step, the circuit board is soldered to the on-site electronics. This offers the additional advantage that the circuit board can be adapted to customer requirements. The multiple first, second and third contact areas are embodied as metallized regions on their areas of their components. The multiple contact areas can, in such case, be two or more—sometimes also a larger number of—contact areas. For the circuit board and the solder paste for connecting circuit board and on-site electronics, conventional solutions are available, and suitable for high temperatures. The circuit board serves, for example, for energy supply of the on-site electronics and/or the processing of electrical, secondary signals, which are produced when processing the electrical, primary signals and transmitted from the on- site electronics.

Advantageously, the circuit board is embodied as a flexible circuit board.

In an embodiment, the first contact areas and the second contact areas are embodied as QFN-, LGA-, DFN-or BGA arrangements. The third contact areas of the circuit board are preferably embodied corresponding to the second contact areas of the on-site electronics. QFN (Quad Flat No Leads), LGA (Land Grid Array) and DFN (Dual Flat No- Lead) describe arrangements, in the case of which the contact areas are integrated planarly on the associated areas of the circuit board or housing. In the case of the BGA (Ball Grid Array) arrangement, in contrast, the contact areas are formed as solder beads. For further processing, firstly, solder paste must be deposited on at least one part of the contact areas.

In an additional embodiment, the sensor element is a pressure sensor element.

Another embodiment provides that the pressure sensor element has a platform and a measuring diaphragm connected with the platform and enclosing a pressure chamber.

The pressure sensor element is, as a rule, sufficiently sensitive that even small differences of the coefficients of thermal expansion of the pressure sensor element and/or elements connected with the pressure sensor element lead to thermomechanical stresses and subsequently to a hysteresis in the pressure signal. This holds not only for the joints between the pressure sensitive element and the on-site electronics, but, instead, also for the on-site electronics. The pressure sensor element is, for example, made of a ceramic, especially corundum, which has a low coefficient of thermal expansion.

In an additional embodiment, the pressure sensor element comprises a capacitive measuring transducer, which has at least a first electrode arranged on the measuring diaphragm and at least a second electrode arranged on the platform, wherein the first and second electrodes face one another, wherein the capacitance between the first electrode and the second electrode depends on a pressure dependent deflection of the measuring diaphragm, wherein at least the second electrode is connected with the measuring-and operating circuit via at least one lead extending through the platform.

Preferably, the on-site electronics is manufacturable in a System-in-Package method. Details for the System-in-Package method are provided above. The measuring-and operating circuit includes at least one integrated circuit and at least one passive element. The on-site electronics represents therewith a complex integrated component. In the context of the System-in-Package method, the coefficient of thermal expansion of the on-site electronics is matched to the coefficient of thermal expansion of the sensor element, such that the on-site electronics and the sensor element have essentially the same coefficients of thermal expansion.

The invention will now be explained in greater detail based on the appended drawing, the figures of which show as follows:

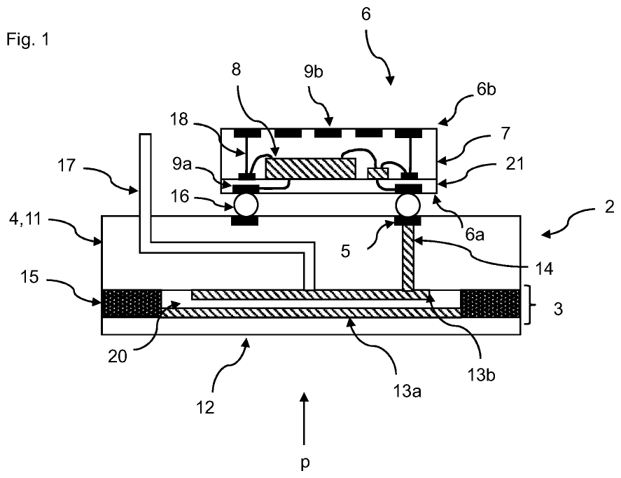

FIG. 1 a schematic view of the connection between the sensor element and the on-site electronics using the example of a pressure sensor element; and

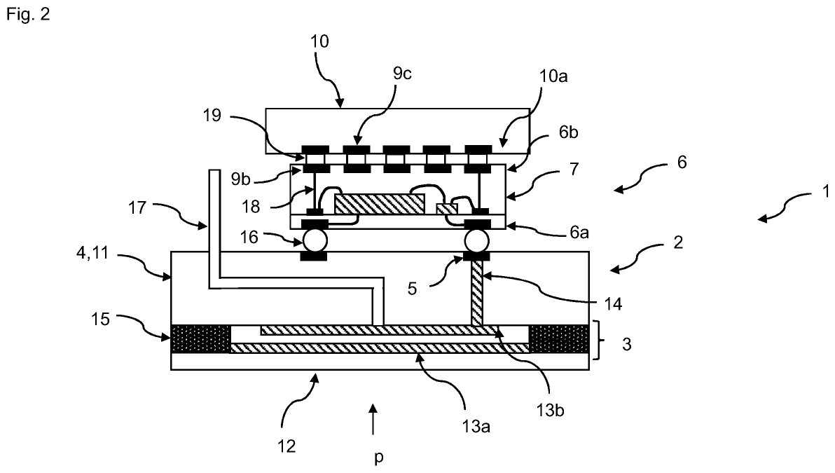

FIG. 2 a schematic view of the measuring device of the invention using the example of a pressure sensor element.

As mentioned above, the measuring device 1 of the invention is usable for a multiplicity of field devices, such as, among others, pressure-and fill level measuring devices. The figures of the appended drawing illustrate the measuring device 1 of the invention using, by way of example, a pressure sensor element 2.

In FIG. 1, first the connection between the pressure sensitive element 2 and the on-site electronics 6 is shown. The pressure sensor element 2 comprises a platform 11, which corresponds to the sensor body 4, as well as a measuring diaphragm 12. Measuring diaphragm 12 and platform 11 are connected by means of a joint 15 and enclose a pressure chamber 20 between them. Diaphragm 12 and platform 11 have mutually facing surfaces. The mutually facing surface of the diaphragm 12 has a first electrode 13a and the mutually facing surface of the platform 11 has at least a second electrode 13b, in order to form the electrical transducer 3, in the case of a pressure sensor element 2 a capacitive transducer 3. Electrical transducer 3 serves for providing measured variable dependent, electrical, primary signals. Acting on the measuring diaphragm 12 is a first pressure p, wherein optionally in the case of a gage-or pressure difference measuring device a second pressure can be led through the pressure supply line 17 into the pressure chamber. A pressure-dependent deflection of the measuring diaphragm 12 influences the capacitance between the two electrodes 13a, 13b. At least the second electrode 13b is connected via a lead 14 with the metallized surface section 5 of the platform 11 and additionally with the measuring-and operating circuit 8.

The on-site electronics 6 includes a housing 7, in which the measuring-and operating circuit 8 is arranged for driving the electrical transducer 3 and processing the electrical, primary signals. Arranged on the first area 6a and on a, by way of example, opposite, second area 6b of the on-site electronics 6 are, in respective cases, a plurality of first contact areas 9a and a plurality of second contact areas 9b. The first area 6a and the second area 6b can also be arranged neighbored or perpendicularly relative to one another. The first contact areas 9a and the second contact areas 9b are, for example, embodied as QFN-, LGA-, DFN-or BGA arrangements. In the example shown in FIG. 1, the first contact areas 9a are soldered via solder beads 16 with the metallized surface section 5. The on-site electronics 6 is optionally manufacturable using a System-in- Package method. In the region of the multiple first contact areas 9a, for example, a substrate 21 is arranged, on which the components of the measuring-and operating circuit 8 are applied. The components of the measuring-and operating circuit 8 are electrically connected with one another.

Furthermore, at least one electrical connection extends between the measuring-and operating circuit 8 and the second contact areas 9b, as well as at least one electrical connection extends between the measuring-and operating circuit 8 and the first contact areas 9a, such that the measuring-and operating circuit 8 can forward electrical, secondary signals, e.g. concerning the processed, primary signals, via the second contact areas 9b to a circuit board 10. This is accomplished by the connection 18.

FIG. 2 shows an example of the measuring device 1 of the invention. Besides the sensor element 2 and the on-site electronics 6, the measuring device 1 includes a circuit board 10. Arranged in a first region 10a of the circuit board 10 are a number of third contact areas 9c, which are soldered with the second contact areas 9b and so form 10 a mechanical and electrical connection between the circuit board 10 and the on-site electronics 6. Circuit board 10 is embodied flexibly, for example.

### LIST OF REFERENCE CHARACTERS

1 measuring device

2 sensor element

3 electrical transducer

4 sensor body

5 metallized surface section

6 on-site electronics

6a first area

6b second area

7 housing

8 measuring-and operating circuit

9a first contact areas

9b second contact areas

9c third contact areas

10 circuit board

10a first region

11 platform

12 measuring diaphragm

13a first electrode

13b second electrode

14 lead

15 joint

16 solder beads

17 pressure supply line

18 connection

19 solder paste

20 pressure chamber

21 substrate

1-7. (canceled)

8. A measuring device for determining and/or monitoring at least one physical and/or chemical, measured variable, comprising:
a sensor element having an electrical transducer for providing measured variable dependent, electrical, primary signals, and a sensor body having at least one metallized surface section;
an on-site electronics having a housing and a measuring-and operating circuit arranged in an interior of the housing for operating the electrical transducer and for processing the primary signals, wherein a first area of the on-site electronics includes a plurality of first contact areas that are mechanically and electrically connected with the at least one metallized surface section of the sensor element and a second area of the on-site electronics includes a plurality of second contact areas; and
a circuit board that includes a plurality of third contact areas in a first region, wherein the circuit board is mechanically and electrically connected with the on-site electronics via the second contact areas and the third contact areas.

9. The measuring device as claimed in claim 8,
wherein the first contact areas and the second contact areas are embodied as Quad Flat No-leads (QFN), Land Grid Array (LGA), Dual Flat No-leads (DFN), or (Ball Grid Array) BGA arrangements.

10. The measuring device as claimed in claim 8,
wherein the sensor element is a pressure sensor element.

11. The measuring device as claimed in claim 10,
wherein the pressure sensor element has a platform and a measuring diaphragm connected with the platform and enclosing a pressure chamber.

12. The measuring device as claimed in claim 11,
wherein the pressure sensor element includes a capacitive measuring transducer having a first electrode arranged on the measuring diaphragm and a second electrode arranged on the platform,
wherein the first and second electrodes face one another and a capacitance between the first electrode and the second electrode depends on a pressure dependent deflection of the measuring diaphragm, and
wherein at least the second electrode is connected with the measuring-and operating circuit via at least one lead extending through the platform.

13. The measuring device as claimed in claim 8,
wherein the circuit board is a flexible circuit board.

14. The measuring device as claimed in claim 8,
wherein the on-site electronics can be produced in a System-in-Package method.
